(19) United States
(12) Patent Application Publication
(10) Pub. No.: US 2024/0309876 A1
(43) Pub. Date: Sep. 19, 2024

(54) ELECTRIC COMPRESSOR

(71) Applicant: KABUSHIKI KAISHA TOYOTA JIDOSHOKKI, Aichi-ken (JP)

(72) Inventors: Yusuke IWASE, Aichi-ken (JP); Shogo URABE, Aichi-ken (JP)

(73) Assignee: KABUSHIKI KAISHA TOYOTA JIDOSHOKKI, Aichi-ken (JP)

(21) Appl. No.: 18/599,890

(22) Filed: Mar. 8, 2024

(30) Foreign Application Priority Data
Mar. 15, 2023 (JP) 2023-040385

(51) Int. Cl. F04D 25/06; F04D 29/58; H05K 7/14; H05K 7/20

(52) U.S. Cl. CPC F04D 25/068; F04D 29/5813; H05K 7/1427; H05K 7/209

(57) ABSTRACT

There is provided an electric compressor in which strain of a board can be suppressed. A first holder is supported by a circuit board and an inverter circuit is mounted thereon. A second holder is supported by the circuit board and an electromagnetic coil is mounted thereon. The inverter circuit mounted on the first holder generates a larger amount of heat than that generated by an electronic component mounted on the second holder. A collar is attached to the first holder. Another collar is attached to the second holder. In a state in which a bolt does not fasten the first holder and the inverter housing, the collar is disposed away from the inverter housing. In a state in which the bolt fastens the first holder and the inverter housing, the inverter circuit is pressed against a heat radiation surface of the inverter housing.

### CROSS REFERENCE TO RELATED APPLICATIONS

This nonprovisional application is based on Japanese Patent Application No. 2023-040385 filed on Mar. 15, 2023 with the Japan Patent Office, the entire contents of which are hereby incorporated by reference.

### BACKGROUND

The present disclosure relates to an electric compressor.

### DESCRIPTION OF THE BACKGROUND ART

Japanese Patent Laying-Open No. 2012-122439 discloses a technology in which a power system unit including a heat-generating element such as an IGBT (Insulated Gate Bipolar Transistor) is fixed to a control board by a lead, the control board is fixed to an installation surface of a main body housing through a bolt, the power system unit is pressed against the installation surface to exchange heat with the installation surface, and the heat generated in the power system unit is radiated.

### SUMMARY

In the technology described in the above literature, when the control board is fixed to the installation surface of the main body housing by the bolt, stress acting on the control board becomes large, with the result that an amount of strain of the control board may be increased. This strain may cause a trouble in an electronic component mounted on the control board or may cause decreased precision of durability evaluation by a thermal shock test.

In the present disclosure, there is proposed an electric compressor in which heat generated by an electronic component can be securely radiated and strain of a board can be suppressed.

In the present disclosure, the following electric compressor is proposed.

An electric compressor includes: a compressing unit that compresses a refrigerant; an electric motor that drives the compressing unit; and a driving circuit assembly including a driving circuit that controls rotation of the electric motor. The driving circuit assembly includes a circuit board, a plurality of electronic components included in the driving circuit, and a first holder and a second holder on each of which at least one electronic component of the plurality of electronic components is mounted, the first holder and the second holder being each supported by the circuit board. The first holder has a first hollow tubular member attached to the first holder. The second holder has a second hollow tubular member attached to the second holder. A heat-generating component is mounted on the first holder, the heat-generating component being an electronic component that generates a larger amount of heat than an amount of heat generated by the electronic component mounted on the second holder. The electric compressor further includes: a housing portion that accommodates the plurality of electronic components and that receives heat conduction from the heat-generating component; a first screw member that extends through the first hollow tubular member to fasten the first holder to the housing portion; and a second screw member that extends through the second hollow tubular member to fasten the second holder to the housing portion. The first hollow tubular member is disposed away from the circuit board. In a state in which the second screw member fastens the second holder and the housing portion and the first screw member does not fasten the first holder and the housing portion, the first hollow tubular member is disposed away from the housing portion. In a state in which the second screw member fastens the second holder and the housing portion and the first screw member fastens the first holder and the housing portion, the first holder is displaced toward the housing portion and therewith the heat-generating component mounted on the first holder is pressed against a heat radiation surface of the housing portion.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a partial cross sectional view showing an overall configuration of an electric compressor according to an embodiment.

FIG. 2 is a schematic configuration diagram of a driving circuit that drives an electric motor.

FIG. 3 is a schematic exploded perspective view of an inverter unit.

FIG. 4 is a schematic diagram of a driving circuit assembly when viewed from below.

FIG. 5 is a schematic diagram view of an inverter housing when viewed in a plan view.

FIG. 6 is a schematic cross sectional view showing the inverter unit before thread fastening.

FIG. 7 is a schematic cross sectional view showing the inverter unit after the thread fastening.

### DESCRIPTION OF THE PREFERRED EMBODIMENTS

The following describes an embodiment based on figures. In the description below, the same reference characters are given to the same parts and components. Their names and functions are also the same. Hence, they are not described in detail repeatedly. It is initially expected to extract freely configurations from the embodiment and combine them freely.

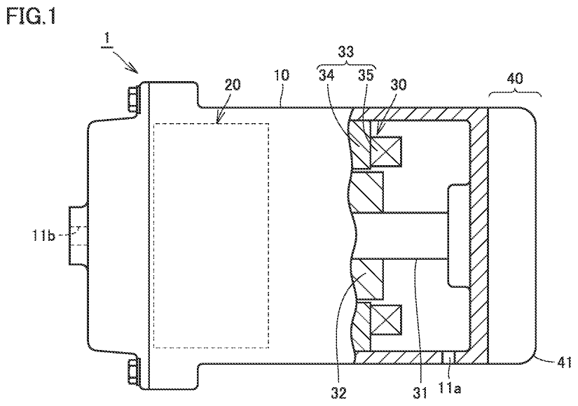

FIG. 1 is a partial cross sectional view showing an overall configuration of an electric compressor 1 according to an embodiment. As shown in FIG. 1, the electric compressor 1 includes a housing 10, a compressing unit 20, an electric motor 30, and an inverter unit 40.

The housing 10 has a substantially circular tubular shape, and accommodates the compressing unit 20 and the electric motor 30 therein. A suction port 11a and a discharge port 11b are formed in the housing 10. An external refrigerant circuit (not shown) is connected to each of the suction port 11a and the discharge port 11b.

The external refrigerant circuit includes a heat exchanger, an expansion valve, and the like, and supplies a refrigerant to the electric compressor 1. The refrigerant is suctioned into the suction port 11a from the external refrigerant circuit. The electric compressor 1 compresses the refrigerant supplied from the external refrigerant circuit. The refrigerant is discharged from the discharge port 11b to the external refrigerant circuit. The electric compressor 1 and the external refrigerant circuit constitute an air conditioning apparatus for cooling and heating. The air conditioning apparatus is mounted on, for example, a vehicle and adjusts a temperature of air in the vehicle compartment.

The compressing unit 20 is configured to compress the refrigerant suctioned from the suction port 11a and discharge the compressed refrigerant from the discharge port 11b. The compressing unit 20 may be of any of a scroll type, a piston type, a vane type, and the like.

The electric motor 30 is configured to drive the compressing unit 20. The electric motor 30 includes, for example, a rotary shaft 31, a rotor 32, and a stator 33. The rotary shaft 31 has a cylindrical shape and is rotatably supported by the housing 10. The rotor 32 has a circular tubular shape and is fixed to the rotary shaft 31. The stator 33 is fixed to the housing 10. The rotor 32 and the stator 33 face each other in a radial direction of the rotary shaft 31. The stator 33 includes a stator core 34 having a circular tubular shape and a coil 35. The coil 35 is formed by winding a conductive wire around a tooth of the stator core 34. The electric motor 30 is an AC rotating electric machine, and may be, for example, an IPM (Interior Permanent Magnet) synchronous electric motor in which a permanent magnet is embedded in the rotor 32.

The inverter unit 40 includes an inverter cover 41. The inverter cover 41 is fixed to the housing 10. A hollow space is formed in the inverter cover 41. A driving circuit of the electric motor 30 is accommodated in the hollow space.

Electric power controlled by the inverter unit 40 is supplied to the electric motor 30, thereby rotating each of the rotor 32 and the rotary shaft 31 at a controlled rotation speed. The compressing unit 20 is driven by this rotation. By driving the compressing unit 20, the refrigerant is suctioned from the external refrigerant circuit into the housing 10 via the suction port 11a, the refrigerant suctioned into the housing 10 is compressed by the compressing unit 20, and the compressed refrigerant is discharged to the external refrigerant circuit via the discharge port 11b.

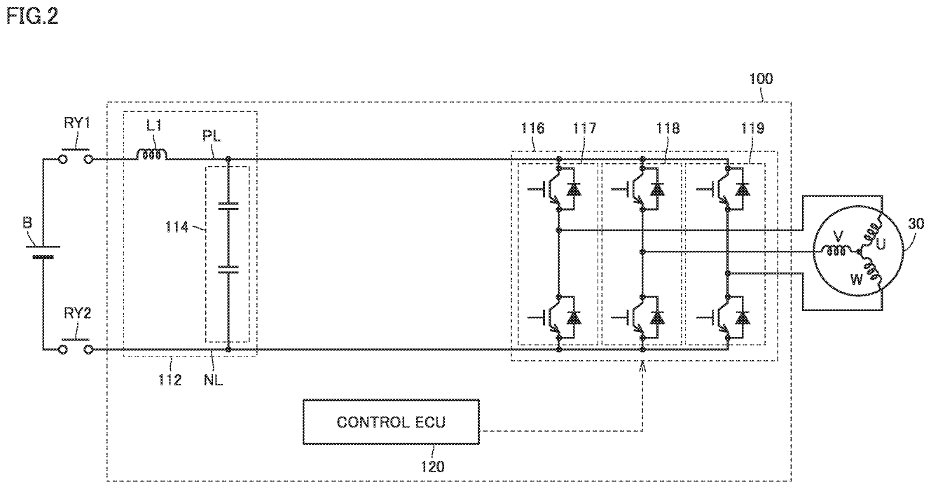

FIG. 2 is a schematic configuration diagram of a driving circuit 100 that drives the electric motor 30. As shown in FIG. 2, the driving circuit 100 includes an electromagnetic coil L1, a capacitor circuit 114, an inverter circuit 116, and a control ECU (Electronic Control Unit) 120.

The electromagnetic coil L1 is connected between the positive electrode of a DC power supply B and a positive electrode bus PL. The capacitor circuit 114 is connected between the positive electrode bus PL and a negative electrode bus NL. The electromagnetic coil L1 and the capacitor circuit 114 constitute a low-pass filter circuit 112.

The inverter circuit 116 includes an U phase arm 117, a V phase arm 118, and a W phase arm 119. Each of the U phase arm 117, the V phase arm 118, and the W phase arm 119 is connected between the positive electrode bus PL and the negative electrode bus NL.

Each of the U phase arm 117, the V phase arm 118, and the W phase arm 119 has switching elements connected in series with each other. Each switching element is, for example, an IBGT, a MOSFET (Metal-Oxide-Semiconductor Field-Effect Transistor), or the like, and is an exemplary power semiconductor.

The U phase arm 117 is connected to one end of an U phase coil of the stator 33 of the electric motor 30. The V phase arm 118 is connected to one end of a V phase coil of the stator 33 of the electric motor 30. The W phase arm 119 is connected to one end of a W phase coil of the stator 33 of the electric motor 30. The other end of each of the U phase coil, the V phase coil, and the W phase coil of the stator 33 of the electric motor 30 is connected to a neutral point.

The inverter circuit 116 is supplied with a DC voltage from the DC power supply B via relays RY1, RY2 and the low-pass filter circuit 112. By switching the transistors included in the U phase arm 117, the V phase arm 118, and the W phase arm 119, the DC voltage is converted into a three-phase AC voltage. The converted AC voltage is supplied to the electric motor 30, thereby controlling rotational driving of the electric motor 30.

The control ECU 120 is configured to include a CPU (Central Processing Unit) and the like and executes a computer program that controls driving of the electric motor 30.

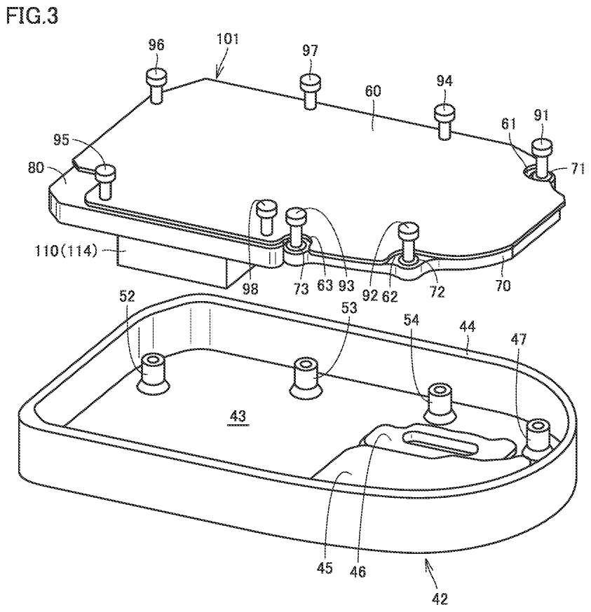

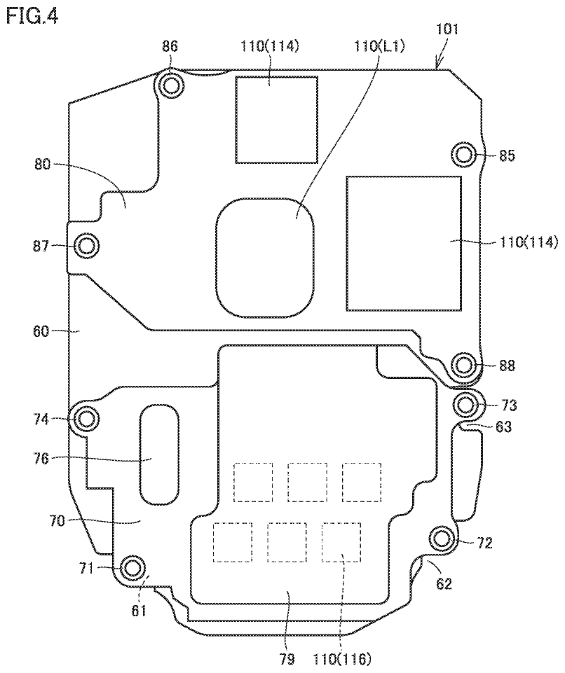

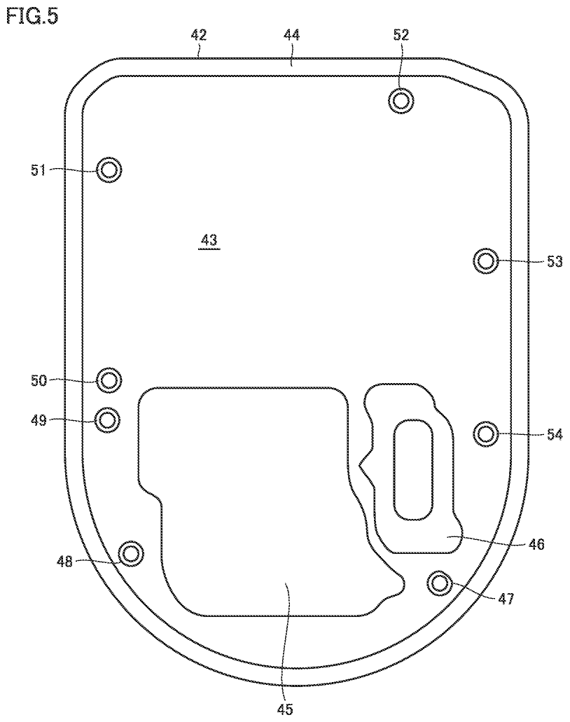

FIG. 3 is a schematic exploded perspective view of the inverter unit 40. The inverter unit 40 includes a driving circuit assembly 101 and an inverter housing 42 shown in FIG. 3. FIG. 4 is a schematic diagram of the driving circuit assembly 101 when viewed from below. FIG. 5 is a schematic plan view of the inverter housing 42.

The inverter housing 42 has a base surface 43 and a side wall portion 44. The base surface 43 has a substantially planar shape. The side wall portion 44 protrudes substantially perpendicularly to the base surface 43 from the peripheral edge portion of the base surface 43. The base surface 43 and the side wall portion 44 form a shape of container having a bottom. The inverter cover 41 described with reference to FIG. 1 is fixed to the side wall portion 44. The driving circuit assembly 101 is accommodated in a hollow space surrounded by the inverter cover 41 and the inverter housing 42. The inverter cover 41 and the inverter housing 42 form a driving circuit accommodation chamber that accommodates the driving circuit 100.

A portion of the housing 10 shown in FIG. 1 may constitute the inverter housing 42. Alternatively, the inverter housing 42 may be configured as a member separated from the housing 10, and may be fixed to the housing 10 using a bolt, for example. The base surface 43 of the inverter housing 42 functions as a partition wall that partitions a motor accommodation chamber that accommodates the electric motor 30 and the driving circuit accommodation chamber that accommodates the driving circuit 100.

The inverter housing 42 has a heat radiation surface 45 and a close contact surface 46 on portions of the base surface 43. The inverter housing 42 has fastening portions 47 to 54. Each of the fastening portions 47 to 54 protrudes substantially perpendicularly from the base surface 43. Each of the fastening portions 47 to 54 has a hollow tubular shape, and has a female-threaded inner peripheral surface. Female-threaded holes are formed in the respective fastening portions 47 to 54.

The driving circuit assembly 101 mainly has a circuit board 60, a first holder 70, a second holder 80, and the driving circuit 100 shown in FIG. 2.

The circuit board 60 supports the first holder 70 and the second holder 80. Each of the first holder 70 and the second holder 80 is, for example, a resin-molded product. At least one electronic component 110 of a plurality of electronic components 110 included in the driving circuit 100 shown in FIG. 2 is mounted on each of the first holder 70 and the second holder 80. A wiring pattern is formed on the circuit board 60, and the electronic components 110 are electrically connected through the wiring pattern. The control ECU 120 (FIG. 2) may also be mounted on the circuit board 60.

As shown in FIG. 4, the inverter circuit 116 is mounted on the first holder 70, for example. The electromagnetic coil L1 and the capacitor circuit 114 are mounted on the second holder 80, for example. The low-pass filter circuit 112 (FIG. 2) is mounted on the second holder 80. The inverter circuit 116 mounted on the first holder 70 generates a larger amount of heat than that generated by each of the electromagnetic coil L1 and the capacitor circuit 114 mounted on the second holder 80. The inverter circuit 116 corresponds to one example of “heat-generating component” serving as the electronic component 110 that generates a larger amount of heat than an amount of heat generated by the electronic component 110 mounted on the second holder 80.

A heat radiation plate 79 is provided to cover the six switching elements included in the inverter circuit 116. The heat radiation plate 79 covers a whole of the inverter circuit 116. The inverter circuit 116 is sandwiched between the first holder 70 and the heat radiation plate 79. Each of surfaces of the heat radiation plate 79 shown in FIG. 4 has a flat shape. The rear surface of the heat radiation plate 79 opposite to its front surface shown in FIG. 4 is in contact with each of the switching elements of the inverter circuit 116. The switching element may directly make surface contact with the rear surface of the heat radiation plate 79. Another member composed of a material having high thermal conductivity may be interposed between the rear surface of the heat radiation plate 79 and the switching element so as to attain thermal contact between the heat radiation plate 79 and the switching element.

Collars 71 to 74 are attached to the first holder 70. Collars 85 to 88 are attached to the second holder 80. Each of the collars 71 to 74 and 85 to 88 has a hollow tubular shape. Typically, each of the collars 71 to 74 and 85 to 88 has a circular tubular shape. Each of the collars 71 to 74, 85 to 88 may be composed of a conductive material such as a metal. In this case, through the collars 71 to 74 and 85 to 88, the circuit board 60 and each of the first holder 70 and the second holder 80 can be electrically connected together and the circuit board 60 can be grounded.

Each of the collars 71 to 74 and 85 to 88, which are each a metal component, is insert-molded when molding the first holder 70 and the second holder 80, and is accordingly molded as a structure in one piece with the first holder 70 and the second holder 80.

As shown in FIG. 3, the circuit board 60 has: a notch portion 61 at a position facing the collar 71; a notch portion 62 at a position facing the collar 72; and a notch portion 63 at a position facing the collar 73.

A bolt 91 shown in FIG. 3 extends through the collar 71 and is fastened to the fastening portion 47 of the inverter housing 42. A bolt 92 extends through the collar 72 and is fastened to a fastening portion 48 (FIG. 5) of the inverter housing 42. A bolt 93 extends through the collar 73 and is fastened to a fastening portion 49 (FIG. 5) of the inverter housing 42. A bolt 94 extends through the collar 74 (FIG. 4) and is fastened to a fastening portion 54 (FIG. 5) of the inverter housing 42.

A bolt 95 extends through the collar 85 (FIG. 4) and is fastened to a fastening portion 51 (FIG. 5) of the inverter housing 42. A bolt 96 extends through the collar 86 (FIG. 4) and is fastened to a fastening portion 52 of the inverter housing 42. A bolt 97 extends through the collar 87 (FIG. 4) and is fastened to a fastening portion 53 of the inverter housing 42. A bolt 98 extends through the collar 88 (FIG. 4) and is fastened to a fastening portion 50 (FIG. 5) of the inverter housing 42.

By fastening the bolts 91 to 98 to the corresponding fastening portions of the inverter housing 42, the circuit board 60, the first holder 70 and the second holder 80 supported by the circuit board 60, and the electronic components 110 mounted on the first holder 70 and the second holder 80 are attached to the inverter housing 42. In this state, the plurality of electronic components 110 are accommodated in the inverter housing 42. The heat radiation plate 79 is in surface contact with the heat radiation surface 45 provided on the base surface 43. Heat is transferred from the inverter circuit 116 to the heat radiation surface 45 via the heat radiation plate 79.

The inverter housing 42 corresponds to one example of “housing portion” that accommodates the plurality of electronic components 110 and that receives heat conduction from the inverter circuit 116 serving as a heat-generating component.

Each of the bolts 94, 95 to 98 extends through the circuit board 60 and is fastened to the inverter housing 42. Since the circuit board 60 is notched around the collars 71 to 73, each of the bolts 91 to 93 does not extend through the circuit board 60.

Each of the collars 71 to 73 attached to the first holder 70 corresponds to one example of “first hollow tubular member”. Each of the collars 85 to 88 attached to the second holder 80 corresponds to one example of “second hollow tubular member”. The collar 74 attached to the first holder corresponds to one example of “third hollow tubular member”.

Each of the bolts 91 to 93, which each extend through the collars 71 to 73 and are each fastened to the inverter housing 42, corresponds to one example of “first screw member”. Each of the bolts 95 to 98, which each extend through the collars 85 to 88 and are each fastened to the inverter housing 42, corresponds to one example of “second screw member”. The bolt 94, which extends through the collar 74 and is fastened to the inverter housing 42, corresponds to one example of “third screw member”. Each of the screw members is not limited to a bolt, but may be a screw or the like.

As shown in FIG. 4, the inverter circuit 116, which is a heat-generating component, is disposed between the collar 71 and the collar 72, and is disposed between the collar 71 and the collar 73. The three collars 71, 72, 73 are disposed around the inverter circuit 116 and are disposed to surround the inverter circuit 116.

A terminal portion 76 is further mounted on the first holder 70. The terminal portion 76 electrically connects the driving circuit 100 and the electric motor 30 shown in FIG. 2. Specifically, the terminal portion 76 has UVW three-phase terminals. The U phase arm 117 and the U phase coil of the electric motor 30 are electrically connected to each other through the U phase terminal of the terminal portion 76. The V phase arm 118 and the V phase coil of the electric motor 30 are electrically connected to each other through the V phase terminal of the terminal portion 76. The W phase arm 119 and the W phase coil of the electric motor 30 are electrically connected to each other through the W phase terminal of the terminal portion 76.

The three-phase terminals of the terminal portion 76 extend through the base surface 43 of the inverter housing 42, and are disposed to extend across the motor accommodation chamber that accommodates the electric motor 30 and the driving circuit accommodation chamber that accommodates the driving circuit 100. In a state in which the first holder 70 is attached to the inverter housing 42, a portion of the terminal portion 76 is in close contact with the close contact surface 46 provided on the base surface 43. The terminal portion 76 is airtightly fixed to the close contact surface 46, thereby ensuring airtightness of the motor accommodation chamber. The terminal portion 76 is an airtight terminal for maintaining airtightness between the motor accommodation chamber and the driving circuit accommodation chamber.

The terminal portion 76 is disposed between the collar 74 and the inverter circuit 116. The terminal portion 76 corresponds to one example of “precision positioning portion” that requires higher positional precision than positional precision required by the inverter circuit 116.

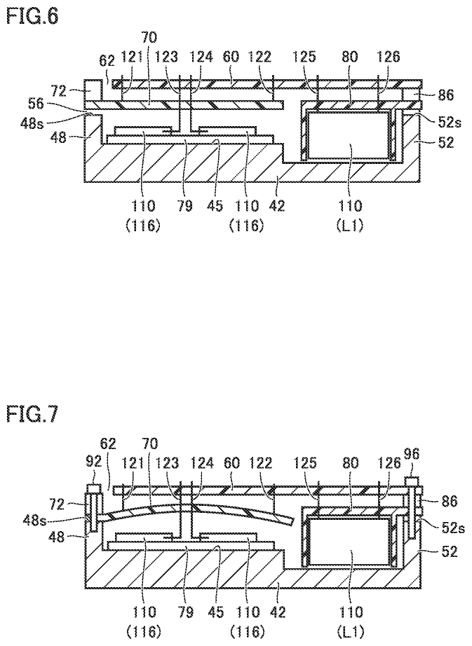

FIG. 6 is a schematic cross sectional view showing the inverter unit 40 before the thread fastening. Each of FIG. 6 and subsequent FIG. 7 illustrates a cross section of the inverter housing 42 and the driving circuit assembly 101 mounted on the inverter housing 42, the cross section being taken along a predetermined folded line. The folded line extends through the collar 72 and the inverter circuit 116, and is folded and extends through the electromagnetic coil L1 and the collar 86.

Each of bus bars 121, 122 shown in FIG. 6 electrically connects the wiring pattern, which is formed on the circuit board 60, and the first holder 70. The first holder 70 is supported by the circuit board 60 via bus bars 121, 122. Each of leads 123, 124 electrically connects the wiring pattern, which is formed on the circuit board 60, and the inverter circuit 116. Each of the leads 125, 126 electrically connects the wiring pattern, which is formed on the circuit board 60, and the electromagnetic coil L1.

The fastening portion 48 has a top surface 48s. An inner peripheral surface of a hole having a bottom and formed to extend from the top surface 48s into the fastening portion 48 is female-threaded, thereby forming a female-threaded hole. The bolt 92 is fastened to the female-threaded hole. The fastening portion 52 has a top surface 52s. An inner peripheral surface of a hole having a bottom and formed to extend from the top surface 52s into the fastening portion 52 is female-threaded, thereby forming a female-threaded hole. The bolt 96 is fastened to the female-threaded hole.

The top surface 48s of the fastening portion 48 comes into contact with the collar 72 by fastening the bolt 92 to the fastening portion 48. The top surface 48s of the fastening portion 48 corresponds to one example of “first contact surface”. The female-threaded hole formed in the fastening portion 48 corresponds to one example of “first female-threaded hole”. The top surface 52s of the fastening portion 52 is in contact with the collar 86. The top surface 52s of the fastening portion 52 corresponds to one example of “second contact surface”. The female-threaded hole formed in the fastening portion 52 corresponds to one example of “second female-threaded hole”.

In the state before the thread fastening shown in FIG. 6, the bolt 92 is not fastened to the fastening portion 48, and the bolt 96 is not fastened to the fastening portion 52. In this state, the collar 86 is in contact with the fastening portion 52. The collar 86 has an end surface in abutment with the top surface 52s of the fastening portion 52. On the other hand, the collar 72 is disposed away from the fastening portion 48. A clearance 56 is formed between the collar 72 and the top surface 48s of the fastening portion 48.

The top surface 48s of the fastening portion 48 and the top surface 52s of the fastening portion 52 are located on the same plane. The collar 72 attached to the first holder 70 and the collar 86 attached to the second holder 80 are disposed to be displaced from each other in the fastening direction of each of the bolts 92, 96 (upward/downward direction in each of FIGS. 6 and 7). Thus, such a configuration is realized that the clearance 56 is formed between the top surface 48s of the fastening portion 48 and the collar 72 and the top surface 52s of the fastening portion 52 and the collar 86 are in contact with each other with no clearance therebetween.

FIG. 7 is a schematic cross sectional view showing the inverter unit 40 after the thread fastening. The bolt 96 extends through the circuit board 60 and the collar 86, and is fastened to the fastening portion 52. Since the collar 86 is in contact with the top surface 52s of the fastening portion 52 even before the thread fastening shown in FIG. 6, the positions of the second holder 80 and the electromagnetic coil L1 with respect to the inverter housing 42 are substantially unchanged even after the bolt 96 is fastened.

The bolt 92 does not extend through the circuit board 60. The bolt 92 extends through the collar 72 via the notch portion 62 formed in the circuit board 60 and is fastened to the fastening portion 48. Before the thread fastening shown in FIG. 6, the clearance 56 is formed between the top surface 48s of the fastening portion 48 and the collar 72. By fastening the bolt 92, the collar 72 is moved toward the fastening portion 48, and the collar 72 is brought into contact with the top surface 48s of the fastening portion 48 as shown in FIG. 7.

On this occasion, at least a portion of the first holder 70 is displaced toward the inverter housing 42. The whole of the first holder 70 may be displaced; however, only a portion of the first holder 70 may be displaced by deflecting the first holder 70 as shown in FIG. 7. The first holder 70 may have a readily deflectable structure by providing the first holder 70 with rigidity smaller than that of the second holder 80.

With the displacement of the first holder 70, the heat radiation plate 79 is pressed against the heat radiation surface 45 of the inverter housing 42. Thus, the heat generated in the inverter circuit 116 is promoted to be conducted to the inverter housing 42 via the heat radiation plate 79 and the heat radiation surface 45. As described with reference to FIG. 1, the refrigerant is suctioned from the suction port 11a into the housing 10. The refrigerant having a low temperature and a low pressure flows in the vicinity of the inverter housing 42, thereby cooling the inverter housing 42 by the refrigerant. In this way, the heat generated by the inverter circuit 116 that generates a large amount of heat can be securely radiated.

The bolt 96 fastens the circuit board 60 and the second holder 80 together. The collar 86 is already in contact with the fastening portion 52 before fastening the bolt 96. On the other hand, the collar 72 is disposed away from the fastening portion 48 before fastening the bolt 92, and is brought into contact with the fastening portion 48 by fastening the bolt 92. The collar 72 is disposed away from the circuit board 60. When fastening the bolt 92, stress transmitted to the circuit board 60 is reduced. Thus, strain of the circuit board 60 can be suppressed.

As shown in FIGS. 3 and 7, since the bolts 95 to 98 extend through the circuit board 60 and are fastened to the inverter housing 42, the circuit board 60 and the second holder 80 can be securely fastened together by the bolts 95 to 98.

As shown in FIGS. 3 and 7, since each of the bolts 91 to 93 does not extend through the circuit board 60, it is possible to securely reduce stress transmitted to the circuit board 60 when fastening the bolts 91 to 93.

As shown in FIG. 3, since the notch portions 61 to 63 are formed in the circuit board 60, it is possible to securely realize a configuration in which the bolts 91 to 93 do not extend through the circuit board 60.

As shown in FIGS. 6 and 7, since the top surface 48s of the fastening portion 48 and the top surface 52s of the fastening portion 52 are located on the same plane, cutting of the inverter housing 42 is facilitated, thereby improving productivity.

As shown in FIG. 4, since the inverter circuit 116 is disposed between the collar 71 and the collar 73, the bolts 91, 93 are fastened to press the inverter circuit 116 toward the heat radiation surface 45, thereby promoting heat radiation from the inverter circuit 116 to the heat radiation surface 45.

As shown in FIG. 4, since the three collars 71, 72, 73 are disposed to surround the inverter circuit 116, the bolts 91 to 93 are fastened to press the inverter circuit 116 toward the heat radiation surface 45, thereby further promoting heat radiation from the inverter circuit 116 to the heat radiation surface 45.

As shown in FIGS. 3 and 4, the arrangement of the collar 74 attached to the first holder 70 is different from the arrangement of the other collars 71 to 73. No notch portion is formed in the circuit board 60 at a position facing the collar 74. The bolt 94, which extends through the collar 74 and is fastened to the fastening portion 54 of the inverter housing 42, extends through the circuit board 60. As with the collars 85 to 88 attached to the second holder 80, the collar 74 is in contact with the inverter housing 42 (the top surface of the fastening portion 54) in a state in which the bolt 94 is not fastened.

The terminal portion 76 is disposed in the vicinity of the collar 74. The terminal portion 76 is mounted on the first holder 70 between the collar 74 and the inverter circuit 116. The terminal portion 76 has the airtight terminal and requires higher positional precision than positional precision required by the inverter circuit 116. By bringing the collar 74 into contact with the top surface of the fastening portion 54 and positioning the collar 74 with respect to the inverter housing 42, the positional precision of the terminal portion 76 can be improved. The airtight terminal of the terminal portion 76 can securely maintain airtightness of the motor accommodation chamber.

In the description of the embodiment, it has been illustratively described that by displacing the positions of the collar 72 and the collar 86, the collar 86 is brought into contact with the top surface 52s of the fastening portion 52 and the clearance 56 is formed between the collar 72 and the top surface 48s of the fastening portion 48. In this case, each of the collars 71 to 74 and 85 to 88 can be constituted of the same component, and the cost can be reduced by using the same components. Instead of this configuration, the length of the collar 72 may be made shorter than the length of the collar 86 so as to form the clearance 56 between the collar 72 and the fastening portion 48 in a state in which the bolt 92 is not fastened. Alternatively, the height of the fastening portion 48 of the inverter housing 42 may be made smaller than the height of the fastening portion 52 to displace the positions of the top surfaces of the fastening portions, thereby forming the clearance 56 between the collar 72 and the fastening portion 48.

In the description of the embodiment, it has been illustratively described that the heat radiation plate 79 is interposed between the inverter circuit 116 and the heat radiation surface 45 of the inverter housing 42 and the heat generated by the inverter circuit 116 is transmitted to the inverter housing 42 via the heat radiation plate 79. The heat radiation plate 79 may not necessarily be provided. All the plurality of switching elements included in the inverter circuit 116 may be brought into surface contact with the heat radiation surface 45 to directly conduct heat from the inverter circuit 116 to the inverter housing 42.

Further, the present specification includes the following disclosure.

### (Supplementary Note 1)

An electric compressor comprising:
a compressing unit that compresses a refrigerant;
an electric motor that drives the compressing unit; and
a driving circuit assembly including a driving circuit that controls rotation of the electric motor, wherein
the driving circuit assembly includes
   a circuit board,
   a plurality of electronic components included in the driving circuit, and
   a first holder and a second holder on each of which at least one electronic component of the plurality of electronic components is mounted, the first holder and the second holder being each supported by the circuit board,
the first holder has a first hollow tubular member attached to the first holder,
the second holder has a second hollow tubular member attached to the second holder, and
a heat-generating component is mounted on the first holder, the heat-generating component being an electronic component that generates a larger amount of heat than an amount of heat generated by the electronic component mounted on the second holder,
the electric compressor further comprising:
a housing portion that accommodates the plurality of electronic components and that receives heat conduction from the heat-generating component;
a first screw member that extends through the first hollow tubular member to fasten the first holder to the housing portion; and
a second screw member that extends through the second hollow tubular member to fasten the second holder to the housing portion, wherein
the first hollow tubular member is disposed away from the circuit board,
in a state in which the second screw member fastens the second holder and the housing portion and the first screw member does not fasten the first holder and the housing portion, the first hollow tubular member is disposed away from the housing portion, and
in a state in which the second screw member fastens the second holder and the housing portion and the first screw member fastens the first holder and the housing portion, the first holder is displaced toward the housing portion and therewith the heat-generating component mounted on the first holder is pressed against a heat radiation surface of the housing portion.

### (Supplementary Note 2)

The electric compressor according to supplementary note 1, wherein the second screw member extends through the circuit board.

### (Supplementary Note 3)

The electric compressor according to supplementary note 2, wherein the first screw member does not extend through the circuit board.

### (Supplementary Note 4)

The electric compressor according to supplementary note 3, wherein the circuit board is provided with a notch portion at a position facing the first hollow tubular member.

### (Supplementary Note 5)

The electric compressor according to any one of supplementary notes 1 to 4, wherein the housing portion has a first contact surface in contact with the first hollow tubular member and a second contact surface in contact with the second hollow tubular member,
a first female-threaded hole to which the first screw member is fastened is formed in the first contact surface,
a second female-threaded hole to which the second screw member is fastened is formed in the second contact surface, and
the first contact surface and the second contact surface are located on the same plane.

### (Supplementary Note 6)

The electric compressor according to any one of supplementary notes 1 to 5, wherein
the first hollow tubular member has a plurality of first hollow tubular members, and
the heat-generating component is disposed between the plurality of first hollow tubular members.

### (Supplementary Note 7)

The electric compressor according to supplementary note 6, wherein the plurality of first hollow tubular members have three or more first hollow tubular members.

### (Supplementary Note 8)

The electric compressor according to any one of supplementary notes 1 to 7, wherein
the first holder has a third hollow tubular member attached to the first holder, and
in a state in which the first screw member does not fasten the first holder and the housing portion, the third hollow tubular member is in contact with the housing portion.

### (Supplementary Note 9)

The electric compressor according to supplementary note 8, wherein a precision positioning portion is mounted on the first holder between the third hollow tubular member and the heat-generating component, the precision positioning portion requiring positional precision higher than positional precision required by the heat-generating component.

Although the embodiments of the present disclosure have been described and illustrated in detail, it is clearly understood that the same is by way of illustration and example only and is not to be taken by way of limitation. The scope of the present disclosure is defined by the terms of the claims, and is intended to include any modifications within the scope and meaning equivalent to the terms of the claims.

What is claimed is:

1. An electric compressor comprising:
a compressing unit that compresses a refrigerant;
an electric motor that drives the compressing unit; and
a driving circuit assembly including a driving circuit that controls rotation of the electric motor, wherein
the driving circuit assembly includes
a circuit board,
a plurality of electronic components included in the driving circuit, and
a first holder and a second holder on each of which at least one electronic component of the plurality of electronic components is mounted, the first holder and the second holder being each supported by the circuit board,
the first holder has a first hollow tubular member attached to the first holder,
the second holder has a second hollow tubular member attached to the second holder, and
a heat-generating component is mounted on the first holder, the heat-generating component being an electronic component that generates a larger amount of heat than an amount of heat generated by the electronic component mounted on the second holder,
the electric compressor further comprising:
a housing portion that accommodates the plurality of electronic components and that receives heat conduction from the heat-generating component;
a first screw member that extends through the first hollow tubular member to fasten the first holder to the housing portion; and
a second screw member that extends through the second hollow tubular member to fasten the second holder to the housing portion, wherein
the first hollow tubular member is disposed away from the circuit board,
in a state in which the second screw member fastens the second holder and the housing portion and the first screw member does not fasten the first holder and the housing portion, the first hollow tubular member is disposed away from the housing portion, and
in a state in which the second screw member fastens the second holder and the housing portion and the first screw member fastens the first holder and the housing portion, the first holder is displaced toward the housing portion and therewith the heat-generating component mounted on the first holder is pressed against a heat radiation surface of the housing portion.

2. The electric compressor according to claim 1, wherein the second screw member extends through the circuit board.

3. The electric compressor according to claim 2, wherein the first screw member does not extend through the circuit board.

4. The electric compressor according to claim 3, wherein the circuit board is provided with a notch portion at a position facing the first hollow tubular member.

5. The electric compressor according to claim 1, wherein
the housing portion has a first contact surface in contact with the first hollow tubular member and a second contact surface in contact with the second hollow tubular member,
a first female-threaded hole to which the first screw member is fastened is formed in the first contact surface,
a second female-threaded hole to which the second screw member is fastened is formed in the second contact surface, and
the first contact surface and the second contact surface are located on the same plane.

6. The electric compressor according to claim 1, wherein
the first hollow tubular member has a plurality of first hollow tubular members, and
the heat-generating component is disposed between the plurality of first hollow tubular members.

7. The electric compressor according to claim 6, wherein the plurality of first hollow tubular members have three or more first hollow tubular members.

8. The electric compressor according to claim 1, wherein
the first holder has a third hollow tubular member attached to the first holder, and
in a state in which the first screw member does not fasten the first holder and the housing portion, the third hollow tubular member is in contact with the housing portion.

9. The electric compressor according to claim 8, wherein a precision positioning portion is mounted on the first holder between the third hollow tubular member and the heat-generating component, the precision positioning portion requiring positional precision higher than positional precision required by the heat-generating component.
